(19) United States
(12) Patent Application Publication
(10) Pub. No.: US 2013/0037084 A1
(43) Pub. Date: Feb. 14, 2013

(54) Photovoltaic Module Light Manipulation for Increased Module Output

(71) Applicants: Mahendran T. Chidambaram, Saratoga, CA (US); S. Daniel Miller, San Jose, CA (US)

(72) Inventors: Mahendran T. Chidambaram, Saratoga, CA (US); S. Daniel Miller, San Jose, CA (US)

(21) Appl. No.: 13/572,640

(22) Filed: Aug. 11, 2012

Related U.S. Application Data
(60) Provisional application No. 61/522,637, filed on Aug. 11, 2011.

(51) Int. Cl. H01L 31/055

(52) U.S. Cl. 136/247

(57) ABSTRACT

Crystalline silicon photovoltaic (PV) cell-based and thin film PV material-based PV modules include a light management material configured to absorb solar energy incident on the PV module across a broad frequency spectrum and re-emit at least a portion of the absorbed solar energy in a narrow frequency spectrum at which the PV cells or PV materials are efficient at converting photon energy to electrical energy.

### RELATED APPLICATIONS

This application claims priority to U.S. Provisional Patent Application 61/522,637, filed 11 Aug. 2011.

### FIELD OF THE INVENTION

The present invention relates generally to photovoltaic (PV) modules, and, in particular, to methods and systems for increasing the energy output of such modules through the introduction of materials that absorb solar (photon) energy across a broad wavelength spectrum and re-emit that energy across a narrow wavelength spectrum over which the active elements of the modules (e.g., photo cells) are highly efficient in converting the photon energy to electrical energy.

### BACKGROUND

A common form of PV device sold today is in the form of a module that includes cells made from rigid monocrystalline or polycrystalline silicon, which cells are electrically interconnected to one another and then encapsulated in ethylene vinyl acetate (EVA), silicone or a similar material. The encapsulant is used to protect the cells from the environment. These traditional PV modules include other materials that provide one or more of the requisite functions of package rigidity, environmental protection, hazard mitigation and/or electrical interconnectivity. FIG. 1 shows a traditional photovoltaic module 10 exploded to show the individual layers.

PV module 10 includes solar cells 16 that are electrically interconnected and are laminated to a clear glass “superstrate” 12, with the collector side of the solar cell facing the glass, with a compliant polymeric encapsuiant layer, often an EVA film 14, on either side of the solar cell and a denser film, such as polyvinyl fluoride (PVF), the most common of which is DuPont's Tediar®, as the hack sheet 18 of the structure. This structure is designed to maximize the amount of solar energy reaching the cells and the amount of electrical energy extracted from these cells while providing protection to the PV cells from the harsh environmental conditions. This structure is also designed to meet various specifications and test requirements of recognized world and local bodies as they relate to PV modules. While FIG. 1 illustrates a typical conventional PV module configuration, the specific materials used may change. As an example, the back sheet may be a multiiayered structure comprised of a very thin PVF film, a polyester or Mylar layer, and a second thin PVF film, commonly referred to as TPT. Alternatively, the back sheet may be comprised of a PVF-Polyester-EVA stack, normally referred to as TPE. While EVA is the most common encapsuiant, other materials have been used, including polyvinyl butyral (PVB). Even in the interconnect wires (tabs) there are variations. While tinned copper ribbon is often used for interconnecting the cells, silver plated copper is sometimes used because of its superior wetting and electrical characteristics.

PV modules are typically fabricated on an automated assembly line that cleans the glass and places it so the side that will eventually face the sun is down, A thin film of the encapsulating material is then laid on top of it to act as the front encapsuiant. In a parallel process, individual solar cells are cleaned, tested and sorted based on output. A group of these cells are wired together serially to form “strings,” typically 10 or 12 cells long. Many of these strings (typically six) are stacked side-by side on top of the encapsuiant film currently laid on the top glass, with the photo-reactive side of the ceils facing the top encapsuiant film. Groups of these strings are wired together or “bussed” so that they make a complete circuit. While this may be anywhere from two strings to all strings in the module, they are normally wired together so that the positive and negative ends of the circuits are beside each other. Another layer of encapsuiant film in then placed on top of the positioned and bussed strings, followed by a layer of the back sheet material. Slits are then cut in the back encapsuiant and back sheet layers at appropriate locations to allow the open positive and negative connections of the circuits formed by the wired-together cell string groups to be brought out of the module.

The module is then introduced into a lamination machine that uses heat, vacuum and physical pressure to laminate the elements of the module together into a single structure. The PV module so laminated is framed along all four edges using a suitable extrusion. This is commonly aluminum but may be any structurally appropriate material that will not decompose in the environment in which the module is to be installed. The frame is sealed so that rain and corrosives cannot get under the frame, thus damaging either the frame or the module itself. A junction box that provides electrical interconnection and required electrical safety circuits is mounted to the back of the module and sealed to protect the electrical interconnections from the outside environment.

The assembled module is then tested in an ideal environment to define its output and associated efficiency. While the testing identifies the actual output, the output is generally defined by the quality and quantity of the PV cells installed in the module and the optical and thermal characteristics of the materials that form the module structure. Typically, the conversion efficiency of any given module is expected to be about 3% to 4% lower than the cells encapsulated into that module under ideal testing conditions.

While less common than PV modules made from rigid monocrystalline or polycrystalline cells, thin-film modules made from crystalline material grown directly onto a transparent conductive oxide (TCO) layer that has been deposited onto the top-glass “superstrate” have gained a following because of their low cost-per-watt of generated power. Low efficiencies and concerns about long-term durability limit their use, but as these modules continue to improve in terms of conversion efficiencies it is anticipated that they will find wider market acceptance because of their lower costs when manufactured in large scale.

The current dominant technologies in the thin-film market are based on Cadmium Telluride (CdTe) and Copper (Indium, Gallium) Selenide (CIGS). Unlike crystalline silicon modules, CdTe and CIGS modules are heterogeneous gate structures is which different materials are laid down in layers to form the valence band. FIG. 2 shows typical CIGS and CdTe construction.

Unlike the c-Si module, which is assembled from components after the cells are manufactured, thin-film modules are manufactured as a whole, with either the glass superstrate or a glass, plastic or metal foil substrate acting as a “mother layer” onto which all other layers are deposited.

Because of the external quantum efficiency (EQE) of thin-film technologies, in particular CIGS and CdTe, these modules are very inefficient at converting solar energy at wavelengths shorter that 450 nm into electricity.

### SUMMARY OF INVENTION

Embodiments of the present invention include crystalline silicon PV cell-based and thin film PV material-based PV modules that include a light management material configured to absorb solar energy incident on the PV module across a broad frequency spectrum and re-emit at least a portion of the absorbed solar energy in a narrow frequency spectrum at which the PV cells or PV materials are efficient at converting photon energy to electrical energy. Where a glass superstrate is employed in the PV module, the light management material may be a layer disposed on a side of the glass superstrate opposite the PV cells, or may be a layer disposed on a same side of the glass superstrate as the PV cells. In this latter case, a polymeric encapsulant layer disposed between the PV cells and the glass superstrate may acts as a carrier for an organic dye which comprises the light management material.

In various instances, the light management material may be a fluorescent dye that is band-compatible with the crystalline silicon PV cells or PV materials. For example, the light management material may be a polymer coating having an infusion of an organic dye of a family of UV absorbing fluorescent dyes that includes, but is not limited to, 4-Dimethylamino-4′-Nitrosilbene (DANS), Stilbene, Chlorophyll (A and/or B), Coumarin dyes and Rhodamine dyes. Alternatively, the light management material may be an organic dye configured to absorb solar energy between 250 nm and 450 nm and re-emit the absorbed energy between 650 nm to 850 nm. Still further, the light management material may be a dye-infused polymer that has been doped with a material used to adjust a fluorescence response of the dye. Such a material may be a high-ionic mobility blending agent chosen to maximize a frequency difference between an absorption spectrum of the dye and an emission spectrum of the dye. For example, the high-ionic mobility blending agent comprises one of: cyclohexane, acetonitrile, dimethyl sulfoxide, chloroform, ethyl acetate, dichloromethane, and diethyl ether.

In PV modules configured in accordance with embodiments of the present invention, the light management material may be any one or more of: a UV stabilized, transparent hydrocarbon; an acrylic; PMMA (poly(methyl methacrylate)); PMBA (poly(methyl methacrylate-co-butyl aery late)); a polycarbonate; a poiyurethane; a blend of silicone; a transparent fluoroethyiene polymer; PTFE (polytetrafluoroethylene); ETFE (ethylene tetrafluoroethylene); FEP (fluorinated ethylene propylene); or FEVE (fluorinated ethylene vinyl ether).

In PV modules configured in accordance with embodiments of the present invention, side walls of one or more of the light management material, the glass superstrate and the polymeric encapsulant layer are covered with a reflective material to direct the re-emitted energy in the narrow frequency spectrum towards the PV ceils or PV material.

### BRIEF DESCRIPTION OF THE DRAWINGS

The present invention is illustrated by way of example, and not limitation, in the figures of the accompanying drawings, in which:

FIG. 1 illustrates components of a conventional PV module based on monocrystalline or polycrystallinc silicon solar ceils;

FIG. 2 illustrates layers of conventional PV modules based on thin film technologies such as CdTe and CIGS; and

FIGS. 3A and 3B illustrate crystalline silicon PV modules configured in accordance with various embodiments of the present invention.

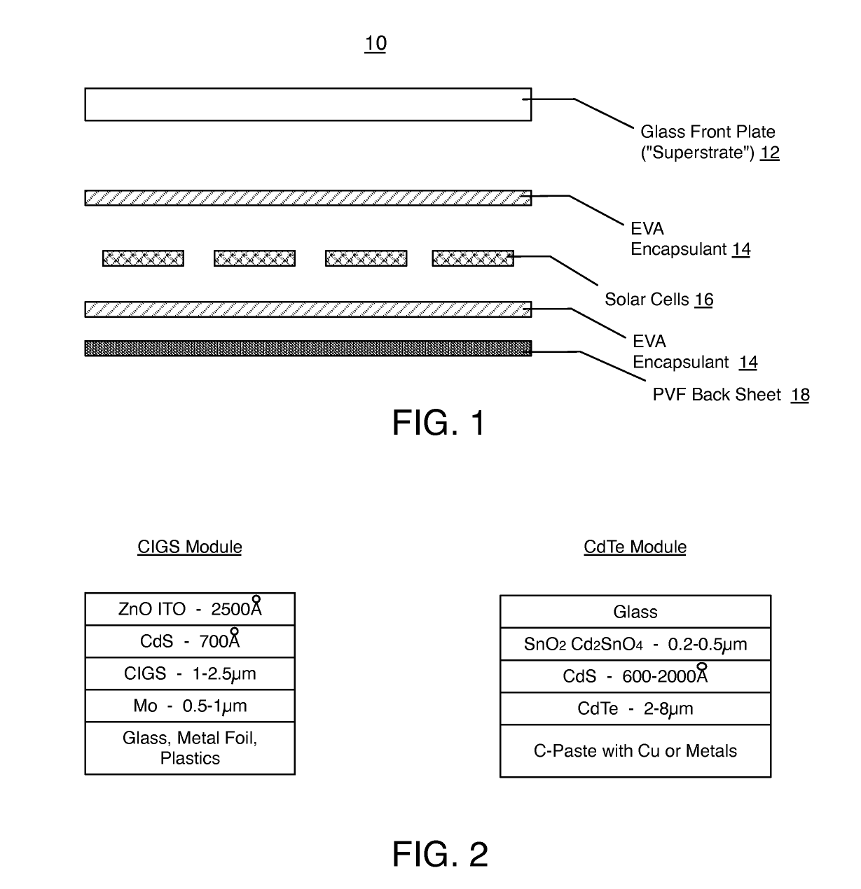

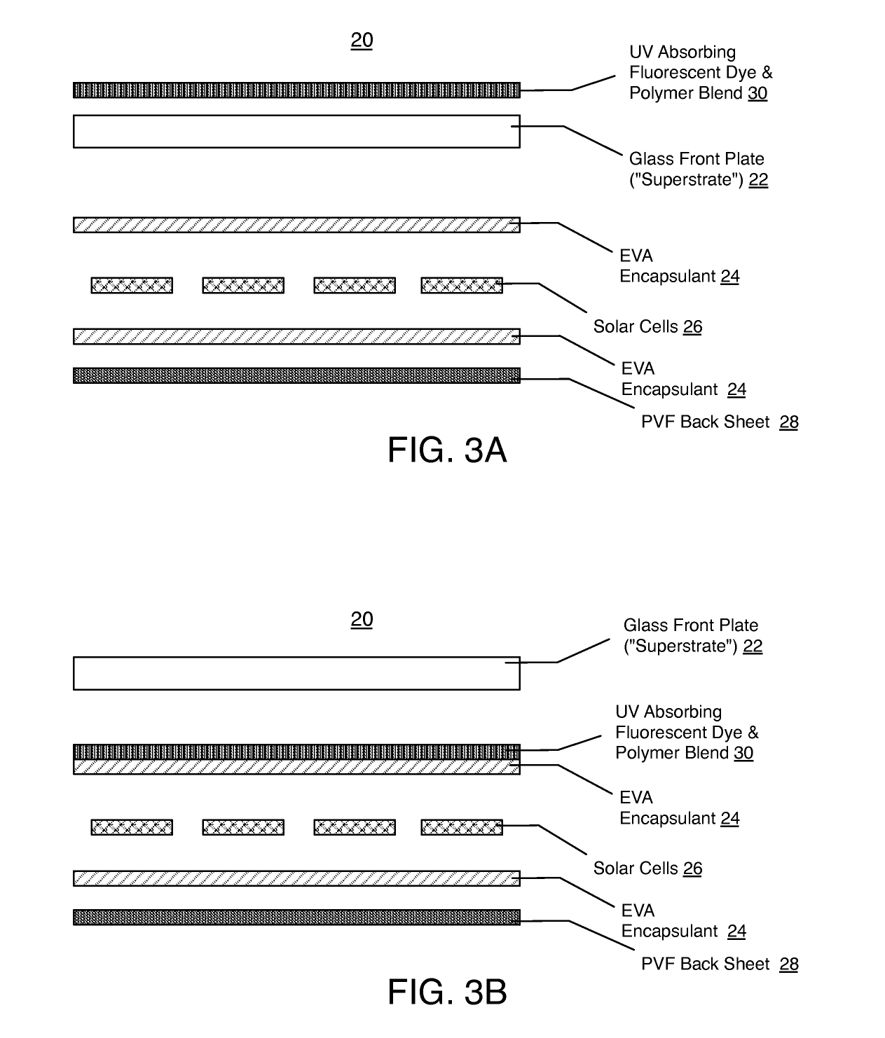

### DETAILED DESCRIPTION

The present invention relates generally to PV modules comprising rigid solar cells made from, monocrystalline or polycrystalline silicon wafers of various sizes and shapes, an encapsulating material to protect the cells, a top-glass layer and, optionally, a rigid or flexible backing sheet. The present invention is also applicable to many other PV technologies, including thin film and dye-sensitized PV modules. While the remaining description will be presented mostly with reference to PV modules made of rigid poly- or mono-crystalline PV cells, the techniques are equally applicable to thin-film modules comprised of thin layers of photo-reactive materials grown directly onto a transparent conductive oxide layer applied to the back of the top-glass layer. Accordingly, readers should recognize that such thin-film modules are likewise regarded as being within the scope of the invention, as more fully defined by the claims following this description.

In one embodiment of the present invention, a PV module having improved energy conversion efficiency (when compared to PV modules of the past) is provided. This improvement is achieved though the conversion of energy from light at undesirable frequencies incident upon the PV module to energy from light at a more desirable frequency using light management materials. Because PV cells convert light (solar) energy most efficiently within a narrow frequency range, by shifting the frequency of the light incident upon the cells the overall energy conversion efficiency of the module that includes the cells can be improved.

PV cells and thin-film modules are by far most efficient at converting light energy at or slightly above the intrinsic band gap energy associated with the valence band of the bulk cell material. For example, silicon has band-gap energy of 1.124 eV. This equates to the energy of light at a wavelength of 1106 nm. Not surprisingly then, silicon PV cells are most efficient at converting light at wavelengths of approximately 800 nm to 1000 nm to electrical energy.

Light from the sun contains much less energy in the 800 nm to 1100 nm spectrum than it does in the 500 nm region. Spectral plots of solar energy show that much more energy is provided by the sun's rays in the blue to blue-green wavelengths (from approximately 450 nm to 550 nm) than in the region that a silicon-based PV cell is most efficient at converting light energy to electricity. The present inventors have recognized that one can increase the efficiency of a silicon-based PV cell (and also reduce the amount of internal heat generated within a PV module) by “shifting” a large portion of the solar energy incident upon a module into the frequency band at which the cells are most efficient in terms of their energy conversion function.

There exists a family of UV-absorbing fluorescent dyes which have the ability to absorb energy in one band of energy (including specific frequency ranges in the UV and visible light spectra) and re-emit that energy as light at a specific frequency determined by the specifics of the dye and the blending of that dye with other stabilizing and spectral enhancement materials. While the present description primarily discusses fluorescent dyes that are band-compatible with monocrystalline and polycrystailine silicon PV ceils, nominally active in the range of 800 nm to 1100 nm, it should be noted that by tuning the dye selection and the stabilizers and fluorescence control additives one can apply the same concept of band-shifting the apparent spectrum of solar radiation to thin film-based PV modules and other PV modules as well (e.g., PV modules based on technologies with a band-gap energy significantly different than that of silicon).

In one embodiment then, the present invention implements frequency shifting of solar radiation by causing such frequency shifts to occur before the light enters the PV module. The clear glass superstrate discussed above typically does not transmit light with a wavelength shorter than 400 nm as efficiently as it transmits light with wavelengths between 400 nm and 1000 nm. Depending on the glass manufacturer and specific glass formula, the light transmittance in the UV range can be less than 50%. Because of this characteristic of the glass superstrate, placing a light management material (such as the fluorescent dye proposed herein) below the top glass may place the resulting PV module at a disadvantage because significant portions of the solar spectrum will never reach the light management material in the first place. At the same time, placing the light management material on the “atmosphere” or “environment” side of the glass superstrate will expose that material to the elements (wind, rain, etc.) and so such an implementation must be undertaken with an eye towards protecting the dyes from oxidation and other photo-deterioration phenomena.

The present invention accommodates both placements of the light management materials. Although it is generally considered superior to place the light management material on top of the solar glass superstrate, e.g., with the dye and carrier materials installed in a blended polymeric coating on top of the glass, it is feasible to apply the same basic methodologies to place the light management material between the glass and the cell. This can be accomplished either by applying the light management material (e.g., in the form of a polymeric blend) between the glass superstrate and the top EVA layer or by using the top EVA layer as the carrier polymer for the organic dye and the high ionic mobility blending agent. Care is taken in this scenario to ensure the structural integrity of the module itself.

A crystalline silicon PV module configured in accordance with an embodiment of the present invention is shown in FIG. 4A. PV module 20 includes solar ceils 26 that are electrically interconnected and are laminated to a clear glass “superstrate” 22, with the collector side of the solar cell facing the glass, with a compliant polymeric encapsulant layer, e.g., an EVA film 24, on either side of the solar cell and a denser film, such as PVF, in one example Tedlar®, as the back sheet 28 of the structure. On the “environment” side of the glass superstrate 22, a UV absorbing coating 30, e.g., consisting of a fluorescent dye in a carrier polymer, is applied. The UV costing 30 includes materials that absorb solar energy across a broad frequency spectrum and re-emit a majority of the absorbed solar energy in a narrow frequency spectrum at which the cells 26 are highly efficient at converting photon energy to electrical energy. FIG. 4B illustrates an alternative embodiment of the PV module 20, this time with the UV absorbing coating integrated with the EVA film 24 disposed between the glass superstrate 22 and the PV cells 26. Alternatively, this top EVA layer 24 may itself be used as the carrier agent for the organic dye and the high ionic mobility blending agent.

Further alternative embodiments of the invention may involve thin-film PV modules similar to those illustrated in FIG. 2, but modified such that a light management material that absorbs solar energy across a broad frequency spectrum and re-emits a majority of the absorbed solar energy in a narrow frequency spectrum at which the thin film module is highly efficient at converting photon energy to electrical energy is included in the material stack. In some cases this modification may entail introduction of one or more layers into the material stack. In other cases, existing layers within the material stack may be modified to be compliant with the desired light frequency absorption and re-emission principles described herein.

In PV modules in which the glass superstrate has been modified by the application of a polymer coating, that polymer coating should have extremely low permeability to a number of gasses commonly found in the environment, including, but not limited to, oxygen, carbon monoxide, carbon dioxide and water in any form. The polymer may be of a family of specifically modified, UV-stabilized, transparent hydrocarbons, including, but not limited to, various acrylics (including specifically modified PMMA (poly(methyl methacrylate)) or PMBA (poly(methyl methacrylate-co-butyl acrylate))), certain polycarbonates, specifically engineered polyurethanes or various blends of silicone suitable for use in the solar cell industry, or it may be of a family of transparent fluoroethylene polymers, including, but not limited to, PTFE (polytetrafluoroethylene), ETFE (ethylene tetrafluoroethylene), FEP (fluorinated ethylene propylene) and FEVE (fluorinated ethylene vinyl ether).

In various embodiments, the present invention provides a PV module that includes a polymer coating having an infusion of a specific organic dye of a family of UV absorbing fluorescent dyes that includes, but is not limited to, 4-Dimethylamino-4′-Nitrosilbene (DANS), Stilbene, Chlorophyll (A and/or B), Coumarin dyes and Rhodamine dyes. The purpose of the dye is to absorb that portion of the solar energy spectrum that is between 250 nm and 450 nm and re-emit those photons in the 650 nm to 850 nm region.

In still farther embodiments of the invention, a PV module includes a light management material such as a dye-infused polymer that has been doped with a material used to adjust the fluorescence response of the dye. This material may be one of a number of high-ionic mobility blending agents, including, but not limited to, cyclohexane, acetonitrile, dimethyl sulfoxide, chloroform, ethyl acetate, dichloromethane, diethyl ether, etc. The blending agent is chosen to maximize the frequency difference between the absorption spectrum of the dye and the emission spectrum of the dye, to maximize the efficiency of the energy conversion and minimize cross-absorption of the emitted spectrum.

PV modules consistent with embodiments of the invention may include those in which the side walls of the polymeric top coating blend, the top glass superstate and the top laminate layer are covered on all sides with a reflective mirror material to redirect the emitted light towards the PV cell and act as a light trapping component.

During manufacture of PV modules consistent with embodiments of the invention, the polymeric top layer is deposited onto the module such that the polymer coating is uniform, is of a controlled thickness and is free of all contaminates including air and nucleated gasses. The polymeric coating layer may be cured in-situ once it is deposited. Control of the thickness of the polymeric coating layer may be effected during manufacture so as to optimize light absorption in a desired spectra and to reduce the internal parasitic light absorption by the polymer blend.

In the example illustrated in FIG. 4A, the UV absorbing fluorescent dyes are encapsulated and installed in a polymeric matrix. The base of the polymeric matrix is selected to be able to withstand UV and oxygen exposure for the lifetime of the module (e.g., more than approximately 25 years). It is also an excellent barrier to oxygen and other molecules that, with the application of solar energy, can cause the organic dyes to deteriorate through a process commonly known as photo-bleaching. The glass superstate may be 2 mm to 4 mm thick and the layers of encapsulant film of EVA, PVB or a similar industry accepted material should be optically clear. One or more rigid solar cells, typically of monocrystalline or polycrystalline silicon, are interconnected serially and arranged in a two-dimensional array. The protective back sheet may be fashioned of PVF, TPT or TPE and is typically colored white to improve module efficiency.

In some embodiments, the light management material may include a fluorescent dye, of appropriate material, blended with polymers, fluorescence modifiers and stabilizers chosen and blended specifically to absorb light in the 300 nm to 450 nm range and to re-emit it through luminescence at one or more wavelengths in the range of 600 nm to 900 nm. The light management material may be coated onto the glass superstrate and then treated to cross-link the polymers in the coating. This can be done either prior to or after the module lamination step. In the latter case, an uncoated module, post-lamination, may be passed on a conveyor system through a plasma cleaning process to make the glass surface hydrophilic, and then subjected to a spray coating of blended materials and heat dried (e.g., at approximately 30° C.) to produce the coated PV module. The latter steps of spray coating the light management material and heat drying maybe performed in a partial vacuum station so as to reduce the possibility of contamination.

While the invention has been described with respect to a limited number of embodiments, those skilled in the art, having benefit of the above description, will appreciate that other embodiments may be devised which do not depart from the scope of the present invention as described herein. In addition, it should be noted that the language used in the specification has been principally selected for readability and instructional purposes, and may not have been selected to delineate or circumscribe the inventive subject matter. The terms used should not be construed to limit the invention to the specific embodiments disclosed in the specification and the claims, but should be construed to include all methods and systems that operate under the claims set forth herein below.

What is claimed is:

1. A photovoltaic (PV) module, comprising crystalline silicon PV cells that are electrically interconnected to one another and are laminated to a clear glass superstrate, with a collector side of each PV cell facing the glass superstrate; a polymeric encapsuiant layer disposed between the PV cells and the glass superstrate; a backing sheet for the PV module disposed on art opposite side of the PV cells than the glass superstrate; and a light management material configured to absorb solar energy incident on the PV module across a broad frequency spectrum and re-emit at least a portion of the absorbed solar energy in a narrow frequency spectrum at which the PV cells are efficient at con veiling photon energy to electrical energy.

2. The PV module of claim 1, wherein the light management material comprises a layer disposed on a side of the glass superstrate opposite the PV cells.

3. The PV module of claim 2, wherein the light management material comprises a fluorescent dye that is band-compatible with the crystalline silicon PV cells, nominally active in the range of 800 nm to 1100 nm.

4. The PV module of claim 1, wherein the light management material comprises a layer disposed on a same side of the glass superstrate as the PV cells.

5. The PV module of claim 4, wherein the light management material comprises a fluorescent dye that is band-compatible with the crystalline silicon PV cells, nominally active in the range of 800 nm to 1100 nm.

6. The PV module of claim 1, wherein the light management material comprises a polymer coating having an infusion of an organic dye of a family of UV absorbing fluorescent dyes that includes, but is not limited to, 4-Dimethyiammo-4′-Nitrosiibene (DANS), Stilbene, Chlorophyll (A and/or B), Coumarin dyes and Rhodamine dyes.

7. The PV module of claim 1, wherein the light management material comprises an organic dye configured to absorb solar energy between 250 nm and 450 nm and re-emit the absorbed energy between 650 nm to 850 nm.

8. The PV module of claim 1, wherein the polymeric encapsulant layer disposed between the PV ceils and the glass superstate comprises a carrier for an organic dye which comprises the light management material.

9. The PV module of claim 1, wherein the light management material comprises a dye-infused polymer that has been doped with a material used to adjust a fluorescence response of the dye.

10. The PV module of claim 9, wherein the material used to adjust the fluorescence response of the dye comprises a high-ionic mobility blending agent, chosen to maximize a frequency difference between an absorption spectrum of the dye and an emission spectrum of the dye.

11. The PV module of claim 10, wherein the high-ionic mobility blending agent comprises one of: cyclohexane, acetonitrile, dimethyl sulfoxide, chloroform, ethyl acetate, dichloromethane, and diethyl ether.

12. A photovoltaic (PV) module, comprising a thin-film PV material as part of a material stack and a light management material configured to absorb solar energy incident on the PV module across a broad frequency spectrum and re-emit at least a portion of the absorbed solar energy in a narrow frequency spectrum at which the PV material is efficient at converting photon energy to electrical energy.

13. The PV module of claim 12, wherein the light management material comprises a fluorescent dye that is band-compatible with the PV material.

14. The PV module of claim 12, wherein the light management material comprises a polymer coating having an infusion of an organic dye of a family of UV absorbing fluorescent dyes that includes, but is not limited to, 4-Dimethyiammo-4′-Nitrosilbene (DANS), Stilbene, Chlorophyll (A and/or B), Coumarin dyes and Rhodamine dyes.

15. The PV module of claim 12, wherein the light management material comprises an organic dye configured to absorb solar energy between 250 nm and 450 nm and re-emit the absorbed energy between 650 ran to 850 nm.

16. The PV module of claim 12, wherein the light management material comprises a dye-infused polymer that has been doped with a material used to adjust a fluorescence response of the dye.

17. The PV module of claim 16, wherein the material used to adjust the fluorescence response of the dye comprises a high-ionic mobility blending agent, chosen to maximize a frequency difference between an absorption spectrum of the dye and an emission spectrum of the dye.

18. The PV module of claim 17, wherein the high-ionic mobility blending agent comprises one of: cyclohexane, acetonitrile, dimethyl sulfoxide, chloroform, ethyl acetate, dichloromethane, and diethyl ether.

19. A PV module as recited in either claim 1 or claim 12, wherein the light management material comprises one of: a UV stabilized, transparent hydrocarbon; an acrylic; PMMA (poly(methyl methacrylate)); PMBA (poly(methyl methacryiate-co-butyl acrylate)); a polycarbonate; a polyurethane; a blend of silicone; a transparent fluoroethylene polymer; PTFE (polytetrafluoroethylene); ETFE (ethylene tetrafluoroethylene); FEP (fluorinated ethylene propylene); or FEVE (fluorinated ethylene vinyl ether).

20. A PV module as recited in either claim 1 or claim 12, wherein side walls of one or more of the light management material, the glass superstrate and the polymeric encapsulant layer are covered with a reflective material to direct the re-emitted energy in the narrow frequency spectrum towards the PV cells or material.
